(19) United States
(12) Patent Application Publication
(10) Pub. No.: US 2005/0181600 A1
(43) Pub. Date: Aug. 18, 2005

(54) Method of forming a semiconductor device having a Ti/TiN/Ti<002>/a1<111> laminate

(75) Inventor: Won-Jun Lee, Ichon-shi (KR)

Correspondence Address: MAYER, BROWN, ROWE & MAW LLP, 1909 K STREET, N.W., WASHINGTON, DC, 20006, US

(73) Assignee: Hynix Semiconductor, Inc.

(21) Appl. No.: 11/101,606

(22) Filed: Apr. 8, 2005

Related U.S. Application Data
(63) Continuation-in-part of application No. 10/396,469, filed on Mar. 26, 2003.
Application No. 10/396,469 is a division of application No. 09/892,536, filed on Jun. 28, 2001, now abandoned.

(30) Foreign Application Priority Data
Jun. 30, 2000 (KR) 2000-37400

(51) Int. Cl. H01L 21/44; H01L 21/4763

(52) U.S. Cl. 438/656; 438/688; 438/653; 438/654

(57) ABSTRACT

Disclosed is a method for forming a multilayer metal thin film capable of improving electromigration reliability. In accordance with an aspect of the present invention, there is provided a method for forming a multilayer metal thin film in a semiconductor device, comprising the steps of: forming a Ti film having an <002> crystal orientation by using an ionized physical vapor deposition method; forming a TiN film on the Ti film in order to form a multilayer stack, wherein the TiN film has an <111> crystal orientation; and forming an aluminum film on the multilayer stack in an <111> crystal orientation. Accordingly, the aluminum metal interconnection according to the present invention increases the <002> orientation of the Ti film and improves the <111> orientation of the aluminum to control the electromigration resistance, by using the IPVD method in forming the Ti film as an underlayer of the aluminum film.

### CROSS REFERENCE TO RELATED APPLICATION

This application is a continuation-in-part of U.S. Ser. No. 10/396,469, filed Mar. 26, 2005. This application, in its entirety, is incorporated herein by reference.

### FIELD OF THE INVENTION

The present invention relates to a method for fabricating a semiconductor device and, more particularly, to a method for forming a multilayer metal thin film capable of improving electromigration reliability.

### DESCRIPTION OF THE PRIOR ART

Generally, an aluminum metal interconnection has been used in semiconductor manufacturing processes with the development of the highly integrated circuits, but the reliability of the device is negatively impacted due to electromigration and stress induced migration. To solve these problems, refractory metal films, such as Ti and W films, have been proposed to prevent hillocks and stress void before or after the formation of the aluminum metal interconnection.

To prevent the increase of resistance of the aluminum metal film after the thermal treatment thereof, a TiN film has been used as an anti-reflective coating film for the aluminum metal film and also to increase resistivity to electromigration.

Alternatively, an aluminum metal film in a multilayer structure containing a TiN film has been proposed and there are reported many results based on aluminum <111> orientation on which the TiN film is used as a lower film. According to the reports, a relatively excellent orientation is often proposed for the TiN film that has an orientation in the <111> direction because the structure of the TiN film may depend upon the different processing conditions. Further, the electromigration resistance, which is caused by an electron wind force and stress in the semiconductor metal wire, depends upon the <111> orientation and the grain distribution in the metal wire.

FIG. 1 is a cross-sectional view illustrating a conventional metal wire in a semiconductor device. A first TiN film 2 is formed on a first Ti film 1, and an aluminum film 3, a second TiN film 4 and a second Ti film 5 are sequentially formed on the first TiN film 2. At this time, the lower films under the aluminum film 3 may affect the structure of the aluminum film 3 because they determine the orientation and the size of the aluminum film 3.

Typically, the aluminum film 3 deposited by the sputtering method is formed in a crystal orientation that is good for the <111> direction and it is known to those skilled in the art that the lifetime of the electromigration increases in proportion to the intensity of the orientation. By reducing the degree of misorientation, an increase in the diffusion velocity through the grains in the aluminum film may be reduced because the EM mismatches, such as hillocks or voids, occur in the vicinity of the grains, not in the <111> direction.

As shown in FIG. 1, in the case where the first Ti film 1 and the first TiN film 2 are formed as an underlayer of the aluminum film 3, the <111> orientation of the aluminum film 3 may be predominant because the first TiN film 2 having the <111> crystal face grows on the <002> crystal face of the first Ti film 1. Also, since the first TiN film 2 prevents the aluminum film 3 from reacting with the first Ti film 1, the resistance of the metal thin film may decrease.

However, as shown in FIG. 2, the first Ti film 1 should be formed to a thickness of approximately 200 Å or more in order that the aluminum film formed on the first Ti/TiN films 1 and 2 have the <111> orientation. Although the first Ti film 1 is formed to a sufficient thickness, the <111> orientation of the aluminum film 3 formed on the first Ti/TiN films is of inferior quality, as compared with the <111> orientation of the aluminum film 3 which is formed on the first Ti film only.

Although there is an increased need for the TiN film in the stacked thin film as a diffusion barrier film between the first Ti film and the aluminum film, the electromigration resistance of the metal thin film deteriorates due to the reduced <111> orientation of the aluminum film when the Ti/TiN films, a stacked thin film, formed by the PVD (physical vapor deposition) method is used as an underlayer stack of the aluminum film.

### SUMMARY OF THE INVENTION

It is, therefore, an object of the present invention to provide a method for forming a multilayer metal thin film capable of improving electromigration reliability in a semiconductor metal interconnection.

It is another object of the present invention to provide a method for reducing an electromigration resistance by improving an <111> orientation of an aluminum film in a semiconductor metal interconnection.

In accordance with an aspect of the present invention, there is provided a method for forming a multilayer metal thin film in a semiconductor device, comprising steps of forming a Ti film having an <002> crystal orientation by using an ionized physical vapor deposition method; forming a TiN film on the Ti film in order to form a multilayer stack, wherein the TiN film has an <111> crystal orientation; and forming an aluminum film on the multilayer stack in an <111> crystal orientation.

In accordance with another aspect of the present invention, there is provided a method for forming a multilayer metal thin film in a semiconductor device, comprising steps of forming a first Ti film using an ionized physical vapor deposition method; forming a TiN film on the first Ti film; forming a second Ti film on the TiN film to increase an <111> crystal orientation of a refractory metal to be formed on the second Ti film; and forming an aluminum film on the second Ti film.

### BRIEF DESCRIPTION OF THE DRAWINGS

Other objects and aspects of the present invention will become apparent from the following description of the embodiments with reference to the accompanying drawings, in which:

FIG. 1 is a cross-sectional view illustrating a method for forming a conventional multilayer metal thin film;

FIG. 2 is a plot showing a deposition thickness of Ti/TiN films on an <111> orientation of an aluminum film according to the prior art;

FIG. 3 is a cross-sectional view illustrating a method for forming a multilayer metal thin film in accordance with an embodiment of the present invention;

FIGS. 4A and 4B are plots showing a variation of the <111> orientation of the aluminum film based on a thickness of a Ti film according to the prior art and the present invention, respectively; and

FIGS. 5A to 5C are cross-sectional views describing a method for forming a multilayer metal thin film in accordance with another embodiment of the present invention.

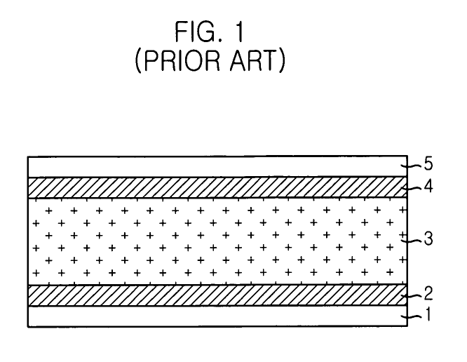

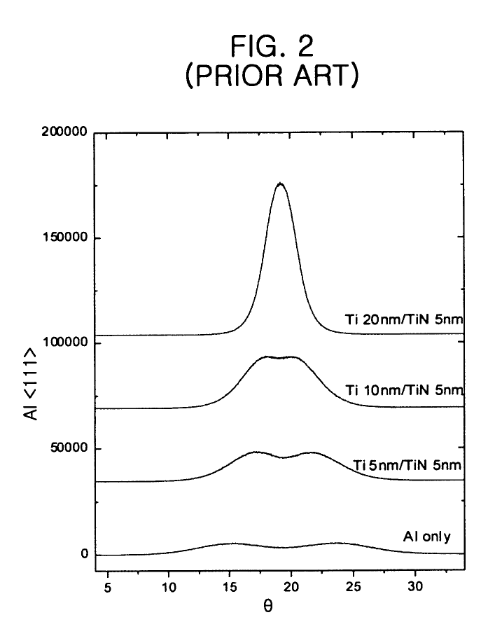

### DETAILED DESCRIPTION OF THE PREFERRED EMBODIMENTS

Hereinafter, a semiconductor device according to the present invention will be described in detail referring to the accompanying drawings.

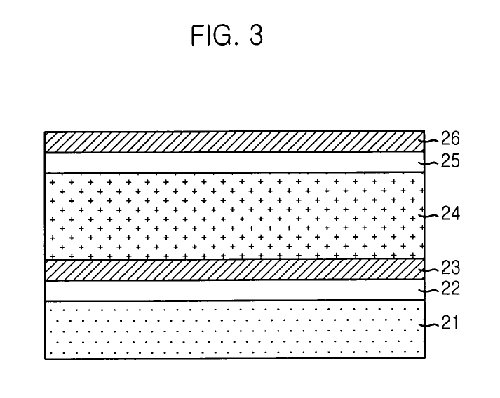

FIG. 3 is a cross-sectional view illustrating a method for forming a multilayer metal thin film in accordance with an embodiment of the present invention.

First, as shown, a first Ti film 22 is formed on a semiconductor substrate 21 at a thickness of approximately 50 to 500 Å using the ionized physical vapor deposition (referred to as “IPVD”) method. In the sputtering method, metal atoms from a target may be ionized and accelerated toward a wafer through AC bias which is applied to a semiconductor substrate. The directness of the ionized atoms may provide an improved step-coverage of the first Ti film 22. In the IPVD method using a radio frequency coil, a hollow cathode or a magnetron, since the kinetic energy of the ionized Ti atoms is high, the first Ti film 22 has an excellent crystal orientation in an <002> direction. Further, in the preferred embodiment of the present invention, the AC bias is in a range of 0 to 500 W and the DC bias is applied to the radio frequency coil in a range of 0.5 to 5 kW when the processing pressure is in a range of approximately 1 to 100 mtor.

After forming the first Ti film 22 in the <002> direction, a first TiN film 23 is formed on the first Ti film 22 to a thickness of 50 to 500 Å. At this time, the first TiN film 23 is deposited by the PVD (Physical Vapor Deposition), MOCVD (Metal Organic Chemical Vapor Deposition) or IPVD method and the first TiN film 23 may have an excellent <111> orientation because the first Ti film 22 has excellent orientation and step-coverage.

Next, after depositing an aluminum film 24 on the first TiN film 23, a second Ti film 25 and a second TiN film 26 are sequentially formed on the aluminum film 24. Typically, the aluminum film 24 may be formed by the PVD (Physical Vapor Deposition) or CVD (Chemical Vapor Deposition) method. In the case of the CVD method, the aluminum film 24 is deposited at a temperature of 150 to 300° C. in a processing chamber having a pressure of 1 to 100 torr and an organism, such as (DMAH) [DiMethylAluminumHydride; (CH₃)₂AlH] or (DMEAA) [DiMethylEthylAmineAlane; AlH₃N(CH₃)₂(C₂H₅)], and their blends may be used as a precursor. Also, the DMAH or DMAH materials used as a precursor may contain an adduct.

As illustrated above, since the first Ti film 22 formed by the IPVD method provides an excellent orientation, the orientation of the first TiN film 23 and the aluminum film 24, which is formed on the first Ti film 22, is considerably improved. Furthermore, since the first TiN film 23 and the aluminum film 24 have excellent orientation in the <111> direction, the aluminum film 24 has a high resistance against electromigration. Accordingly, by improving the <111> orientation of the aluminum film 24 and increasing the resistance against electromigration, it is possible to make the semiconductor devices highly integrated in a chip on the basis of the improved fine structure of the aluminum film 24.

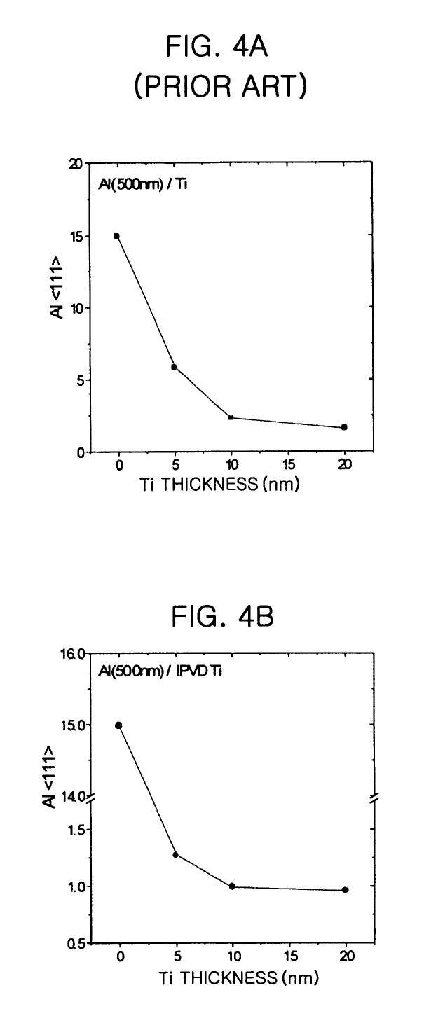

As shown in FIG. 4B, since the TiN film 23 and the aluminum film 24 are deposited after forming the first Ti film 22 by the IPVD method, the <002> orientation of the first Ti film 22 may be improved so that the orientation of the first TiN film 23 and the aluminum film 24 is of superior quality. In other words, compared with the conventional Ti film shown in FIG. 4A, which is required to be formed to a thickness of about 200 Å, the first Ti film 22 formed by the IPVD method according to the present invention contributes to improved <111> orientation of the aluminum film 24 even if its deposition thickness is thinner than that of the conventional Ti film.

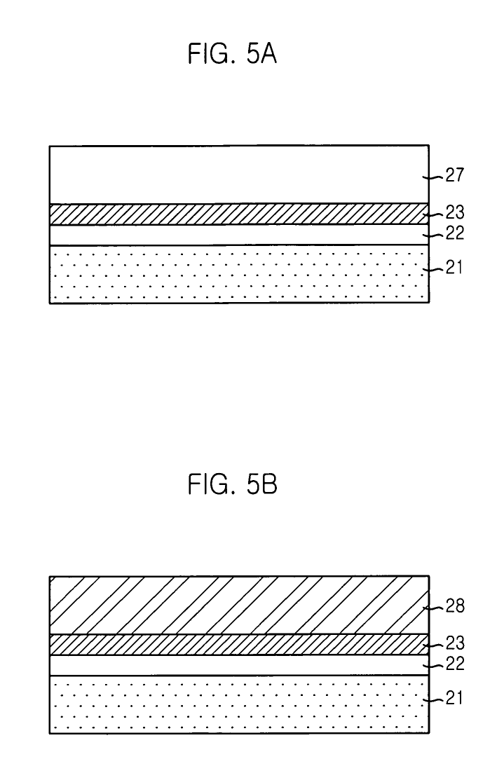

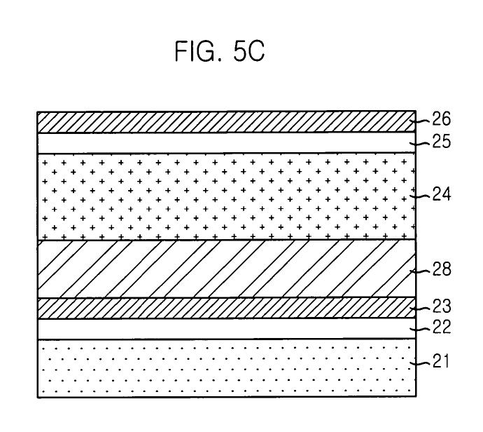

FIGS. 5A to 5C are cross-sectional views describing a method for forming a multilayer metal thin film in accordance with another embodiment of the present invention.

As shown, as compared with FIG. 3, there are different steps for forming a tungsten layer 57 and a Ti film 58 under an aluminum film 54.

First of all, a first Ti film 52 is formed on a semiconductor substrate 51 and a first TiN film 53 is formed on the first Ti film 52. Until these steps, the method in accordance with another embodiment of the present invention can be similar to the method described in FIG. 3. Then, referring to FIG. 5A, the tungsten layer 57 is formed on the first TiN film 53.

As shown in FIG. 5B, the tungsten layer 57 is eliminated by etch-back process and, then, a second Ti film 58 is formed on the first TiN film 53 to thereby improve <111> orientation and electromigration resistance of the aluminum film 54. Particularly, to improve the <111> orientation of an aluminum film, the first Ti film 52 is formed by using the IPVD method and the second Ti film 58 is formed by using one of the PVD method and the IPVD method. Further, the second Ti film 58 is formed to a thickness of approximately 50 to 500 Å.

Then, the aluminum film 54 is formed on the second Ti film 58. After forming the aluminum film 54, a third Ti film 25 is formed on the aluminum film 54 and a second Ti film 26 is formed on the third Ti film 25. Herein, these steps for forming the aluminum film 54, the third Ti film 25 and the second Ti film 26 are similar to above described steps shown in FIG. 3.

As apparent from the above, the aluminum metal interconnection according to the present invention increases the <002> orientation of the Ti film and improves the <111> orientation of the aluminum to control electromigration resistance, by using the IPVD method in forming the Ti film as an underlayer of the aluminum film. The improved <111> orientation of the aluminum film may improve the reliability and fine structure of a metal wire in the resulting metal interconnection and increase the degree of integration of semiconductor devices by improving the size of grains and the surface roughness of the aluminum film with the increase of electromigration resistance. Also, the IPVD method according to the present invention may decrease the thickness of the Ti film which is used to improve the <111> orientation of the aluminum film, thereby lengthening the expected life span of the Ti target and the processing kit with the improved yield of semiconductor devices.

Although the preferred embodiments of the present invention have been disclosed for illustrative purpose, those skilled in the art will appreciate that various modifications, additions and substitutes are possible, without departing from the scope and spirit of the present invention as described in the accompanying claims.

1. A method for forming a multilayer metal thin film in a semiconductor device, comprising steps of:
forming a first Ti film using an ionized physical vapor deposition method;
forming a TiN film on the first Ti film;
forming a tungsten film on the TiN film with a subsequent etch-back process;
forming a second Ti film on the TiN film to increase an <111> crystal orientation of a succeeding metal to be formed on the second Ti film; and
forming an aluminum film on the second Ti film as the succeeding metal.

2. The method as recited in claim 1, wherein the second Ti film has an <002> orientation and wherein the second Ti film is formed by a PVD (Physical Vapor Deposition) or IPVD (Ionized Physical Vapor Deposition) method.

3. The method as recited in claim 1, wherein the second Ti film is formed at a thickness of approximately 50 to 500□.

4. The method as recited in claim 1, wherein the ionized physical vapor deposition method applies AC bias of 0 to 500 W to the substrate.

5. The method as recited in claim 4, wherein the AC bias of 0 to 500 W is applied to the substrate at a pressure of 1 to 100 mtorr.

6. The method as recited in claim 1, wherein the first Ti film is formed at a thickness of approximately 50 to 500 □.

7. The method as recited in claim 1, wherein the TiN film is formed by a PVD (Physical Vapor Deposition), MOCVD (Metal Organic Chemical Vapor Deposition) or IPVD method and wherein the TiN film is formed at a thickness of approximately 50 to 500□.

8. The method as recited in claim 1, wherein the aluminum film is formed by a PVD or CVD method.

9. The method as recited in claim 1, wherein a precursor to form the aluminum film in a CVD method is one of DMAH (CH₃)₂AlH, DMEAA (AlH₃N(CH₃)₂(C₂H₅), and their mixtures.

10. The method as recited in claim 9, wherein the aluminum film is formed at a temperature of 150 to 300□ and in a processing chamber having a pressure of 1 to 100 torr.
